(19) United States
(12) Patent Application Publication
(10) Pub. No.: US 2026/0205737 A1
(43) Pub. Date: Jul. 16, 2026

(54) SegMEMS

(71) Applicant: Infineon Technologies AG, Neubiberg (DE)

(72) Inventors: Claudio Falco, München (DE); Marc Füldner, Neubiberg (DE); Andreas Wiesbauer, Pörtschach a. W. (AT); Jose Luis Ceballos, Villach (AT)

(21) Appl. No.: 19/016,803

(22) Filed: Jan. 10, 2025

(51) Int. Cl. H04R 7/06; H04R 3/00; H04R 17/02

(52) U.S. Cl. CPC H04R 7/06; H04R 3/00; H04R 17/02; H04R 2201/003

(57) ABSTRACT

A digital microphone includes a segmented microelectromechanical system (MEMS) device for generating a first signal having a first response to an ambient signal and for generating a second signal having a second response to the ambient signal; and a combination circuit for dynamically combining the first signal and the second signal to generate a combined output signal.

### TECHNICAL FIELD

The present invention relates generally to microphones including segmented Microelectromechanical system (MEMS) devices (SegMEMS), and to a corresponding method.

### BACKGROUND

MEMS microphone with single signal MEMS devices face an inherent tradeoff between sensitivity to low input pressures and resilience to high input pressures. High-sensitivity microphones excel at processing low input pressure signals, resulting in an improved signal-to-noise ratio (SNR). However, this increased sensitivity comes at the cost of a lower acoustic overload point (AOP), making them prone to distortion when exposed to high input pressures. Conversely, low-sensitivity microphones can handle higher sound pressure levels without distorting, but struggle to detect subtle acoustic details, leading to a poorer SNR. This balancing act between SNR and AOP presents a critical design challenge, requiring engineers to carefully consider the intended application when selecting or designing microphones.

### SUMMARY

According to an embodiment, a system comprises a segmented microelectromechanical system (MEMS) device configured for generating a first signal having a first response to an ambient signal and for generating a second signal having a second response to the ambient signal; and a combination circuit configured for dynamically combining the first signal and the second signal to generate a combined output signal.

According to an embodiment, a microelectromechanical (MEMS) device comprises a segmented membrane; and a support structure for supporting the segmented membrane, wherein the segmented membrane comprises a high signal-to-noise (SNR) region and a high acoustic overload point (AOP) region.

According to an embodiment, a method comprises generating a first input signal comprising a high signal-to-noise (SNR) version of a single input signal; generating a second input signal comprising a high acoustic overload point (AOP) version of the single input signal, wherein the first input signal and the second input signal have different responses to the single input signal; dynamically combining the first input signal and the second input signal; and generating a combination output signal bounded by a first input signal response and a second input signal response.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1-3 are graphs of an output signal of a microphone, particularly illustrating sensitivity characteristics of a single signal MEMS according to the prior art;

FIG. 4 is a graph of a combined output signal of a microphone, particularly illustrating sensitivity characteristics of a segmented membrane MEMS according to an embodiment;

FIG. 5 is a system including a segmented MEMS device implemented on a first integrated circuit, and an ASIC implemented on a second integrated circuit, according to an embodiment;

FIGS. 6A, 6B, 6C, 6D and 6E are plan view diagrams of segmented MEMS devices, according to embodiments;

FIG. 7A is a cross-sectional view of a segmented MEMS device, according to an embodiment;

FIG. 7B is a graph of the output characteristics of the segmented MEMS device of FIG. 7A;

FIGS. 8A, 8B, 8C, 8D and 8E are cross-sectional views of segmented MEMS devices, according to embodiments;

FIGS. 9A and 9B are block diagrams of digital microphones including a segmented MEMS device and a combination circuit, according to embodiments; and

FIGS. 10A and 10B are schematic diagrams of combination circuits, according to embodiments.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

In the following detailed description, reference is made to the accompanying drawings, which form a part hereof and in which are shown by way of illustrations specific embodiments in which the invention may be practiced. It is to be understood that other embodiments may be utilized and structural or logical changes may be made without departing from the scope of the present invention. For example, features illustrated or described for one embodiment can be used on or in conjunction with other embodiments to yield yet a further embodiment. It is intended that the present invention includes such modifications and variations. The examples are described using specific language, which should not be construed as limiting the scope of the appending claims. The drawings are not scaled and are for illustrative purposes only. For clarity, the same or similar elements have been designated by corresponding references in the different drawings if not stated otherwise.

According to embodiments, a microphone comprises a segmented microelectromechanical system (MEMS) device configured for generating a first signal having a first response to an ambient signal and for generating a second signal having a second response to the ambient signal; and a combination circuit configured for dynamically combining the first signal and the second signal to generate a combined output signal.

According to embodiments, the MEMS device comprises a MEMS sensor with two active regions providing a relatively high output signal at low to medium input pressures, and a reduced signal at high input pressures to enable the highest SNR at low input pressures and no voltage overloading at high pressures (high AOP). Embodiments of segmented MEMS sensors (SegMEMS) and combination circuits are described in detail below.

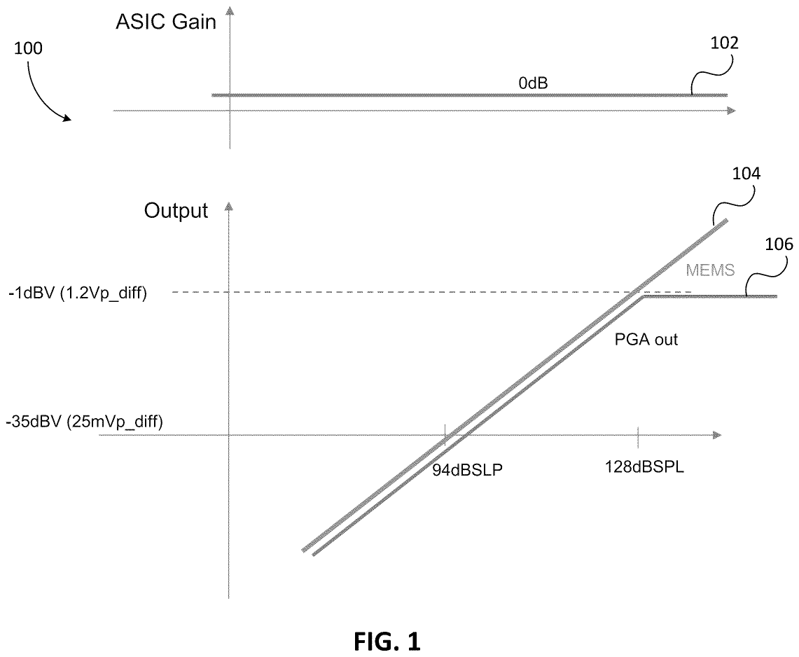

FIGS. 1-3 are graphs of an output signal of a MEMS sensor and an output signal of a microphone, particularly illustrating sensitivity characteristics of a single signal membrane (unsegmented) MEMS sensor according to the prior art. The microphone includes an unsegmented MEMS sensor coupled to ASIC for processing the output of the MEMS sensor. While specific numbers are used for input pressure (in decibels sound pressure level, “dBSPL”), gain (in decibels, “dB), and output voltage (in decibels referenced to voltage, “dBV”), these are only examples associated with a specific microphone.

FIG. 1 is a graph 100 of limited MEMS sensitivity, which results in limited SNR. In the example of FIG. 1, the ASIC gain 102 is set to unity, i.e. zero dB. The MEMS sensor provides a linear output response 104. The corresponding signal output 106 of programmable amplifiers (PGA) in the ASIC is saturated at an input pressure of about 128 dBSPL.

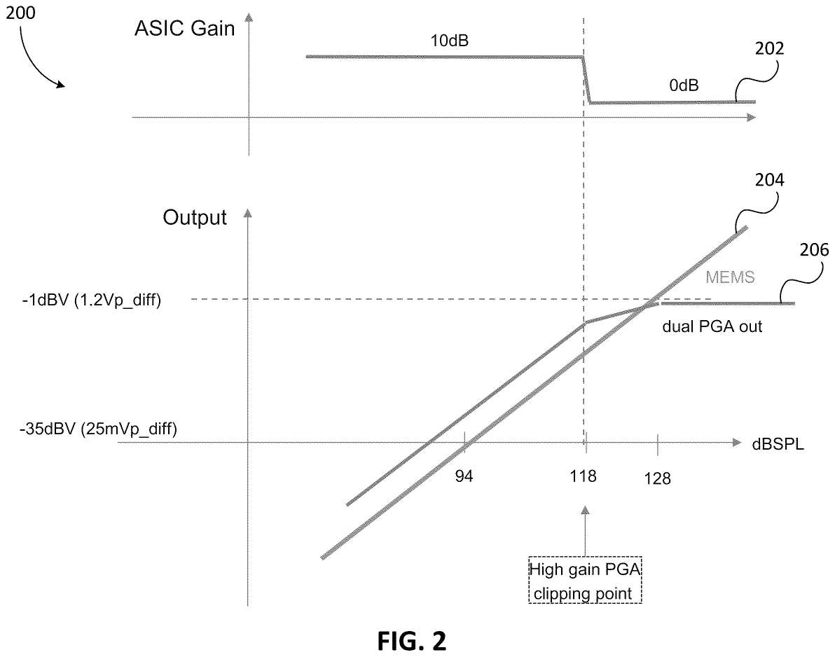

FIG. 2 is a graph 200 of limited MEMS sensitivity, which results in better SNR in a logarithmic ASIC example. In the example of FIG. 2, logarithmic amplifiers are used in the ASIC to provide an ASIC gain 202 of about 10 dB at low and medium input pressures, transitioning to an ASIC gain 202 of about zero dB at high input pressures. The linear output 204 of the MEMS sensor and the signal output 206 of the ASIC are shown in FIG. 2. While this solution provides a better SNR at the same clipping point compared to the example of FIG. 1, there is a transition regime that may cause audio artefacts.

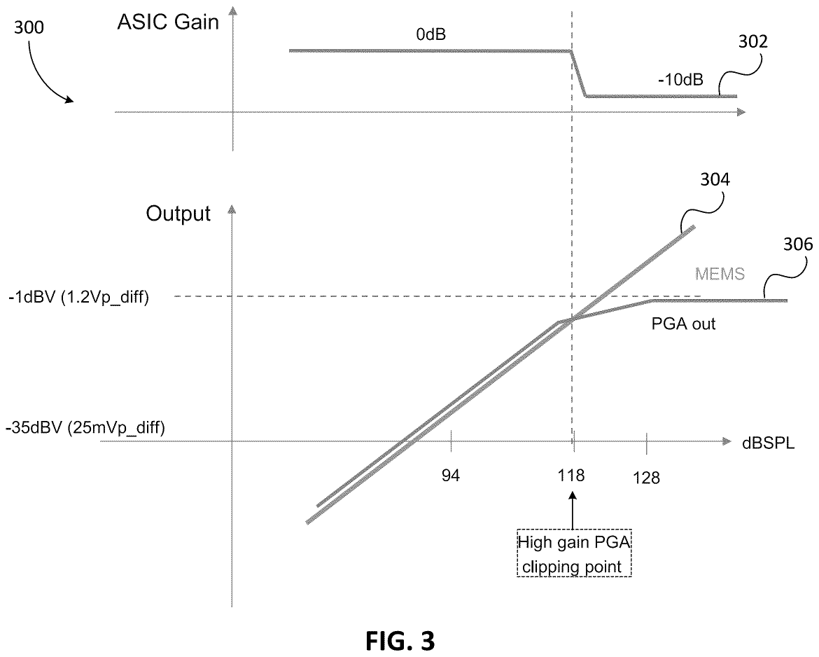

FIG. 3 is a graph 300 of increased MEMS sensitivity, which results in better SNR in another logarithmic ASIC example. In the example of FIG. 3, logarithmic amplifiers are used in the ASIC to provide an ASIC gain 302 of about zero dB at low and medium input pressures, transitioning to an ASIC gain 202 of about −10 dB at high input pressures. The linear output 304 of the MEMS sensor and the signal output 306 of the ASIC are shown in FIG. 3. While this solution also provides a better SNR at the same clipping point compared to the example of FIG. 2, there is also a transition regime that may cause audio artefacts.

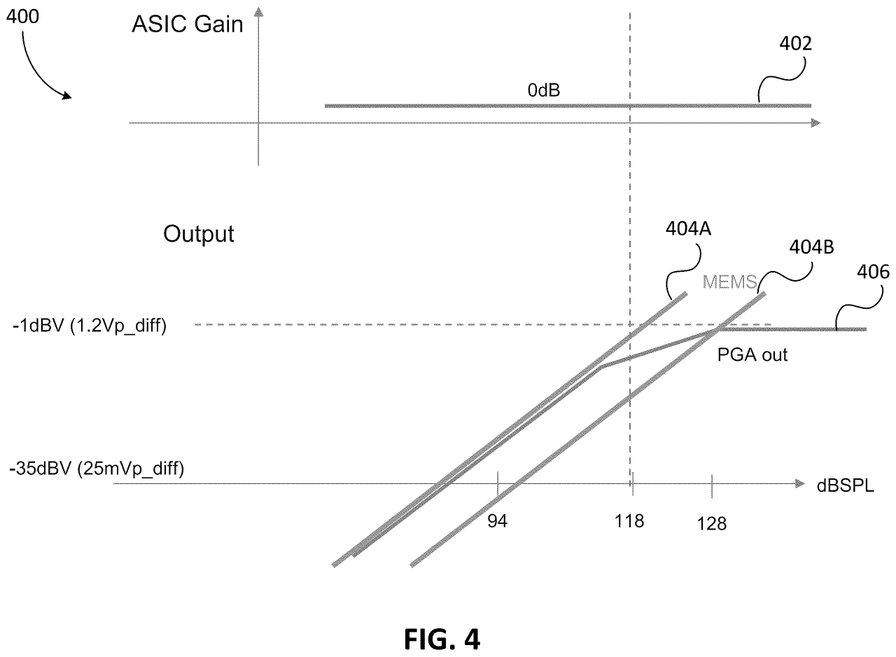

FIG. 4 is a graph 400 of a dual range MEMS sensor with increased sensitivity, which results in high SNR and a linear ASIC, according to an embodiment. In the embodiment of FIG. 4 a linear ASIC gain 402 of zero dB is used. The segmented MEMS sensor generates a relatively high gain response 404A for use at low and medium input pressures, and a relatively low gain response 404B for use at high input pressures. The dual range MEMS sensor effectively has a single input response to the same ambient sound wave signal, but has two output signals that are combined to provide a relatively high SNR and a relatively high AOP. The combined output signal 406 of the ASIC provides a smoother transition (from a linear response to the saturated response) with no sharp high gain PGA clipping point. In FIG. 4, the combined output signal 406 is bounded by the high gain response 404A and the low gain response 404B before entering the saturation mode.

The embodiment of FIG. 4 advantageously enables an effective single PGA (in terms of power dissipation), high linearity in the MEMS output voltage, and a more of a “smooth” transition from linear to saturated operation, which may reduce unwanted audio artifacts. The high gain PGA clipping point is therefore substantially reduced. Embodiments of the segmented MEMS sensor and combination circuits for combining the two segmented MEMS sensor outputs are described in further detail below.

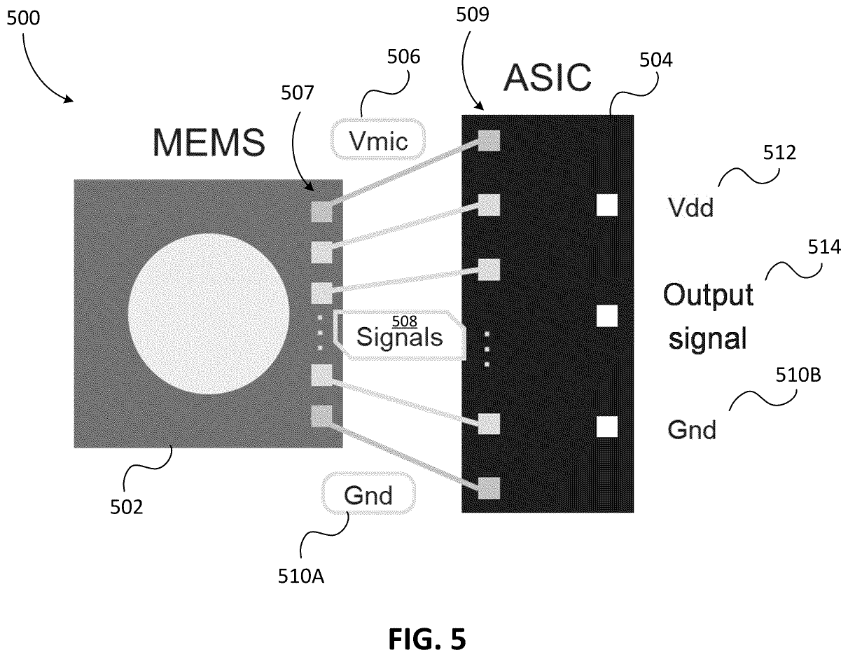

FIG. 5 is a system 500 including a segmented MEMS device implemented on a first integrated circuit 502, and an ASIC implemented on a second integrated circuit 504, according to an embodiment. The segmented MEMS device implemented on the first integrated circuit 502 comprises a plurality of bonding pads 507 including an output voltage pad coupled to interconnect 506 (Vmic), a ground pad coupled to interconnect 510A, and various signal pads coupled to a plurality of signal interconnects 508. The ASIC implemented on the second integrated circuit 504 comprises a corresponding plurality of bonding pads 509 including an input voltage pad coupled to interconnect 506 (Vmic), a ground pad coupled to interconnect 510A, and various signal pads coupled to the plurality of signal interconnects 508. The ASIC implemented on the second integrated circuit 504 also includes a separate VDD pad 512, an output signal pad 514, and another external ground pad 510B. The separate integrated circuit embodiment of FIG. 5 is only an example of one particular embodiment, and other combinations of the MEMS sensor and processing circuitry can be used to include only one integrated circuit, or the use of additional integrated circuits. Specific details of the MEMS sensor and the ASIC are described below.

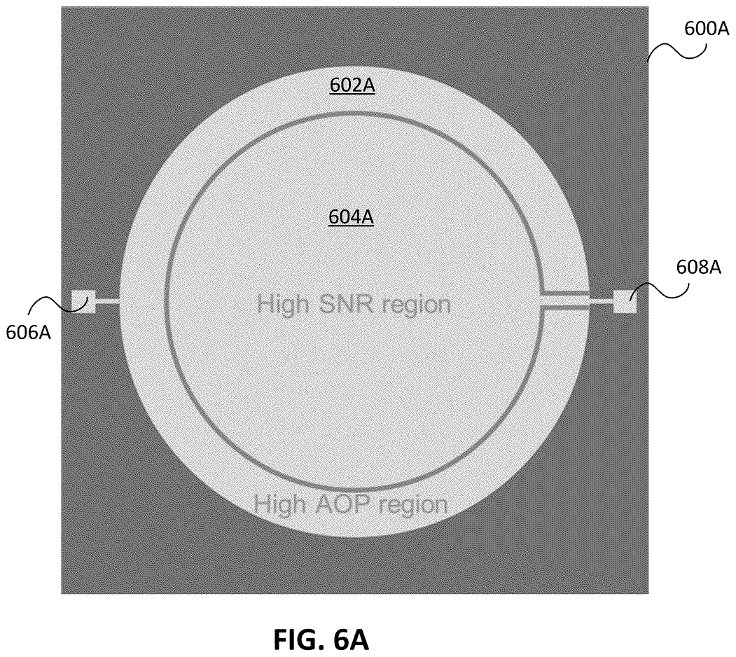

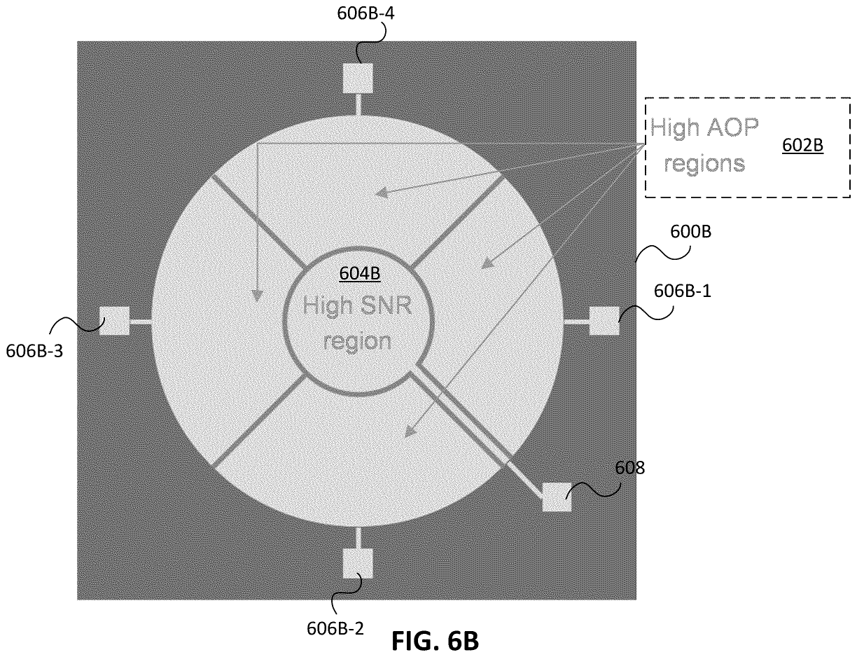

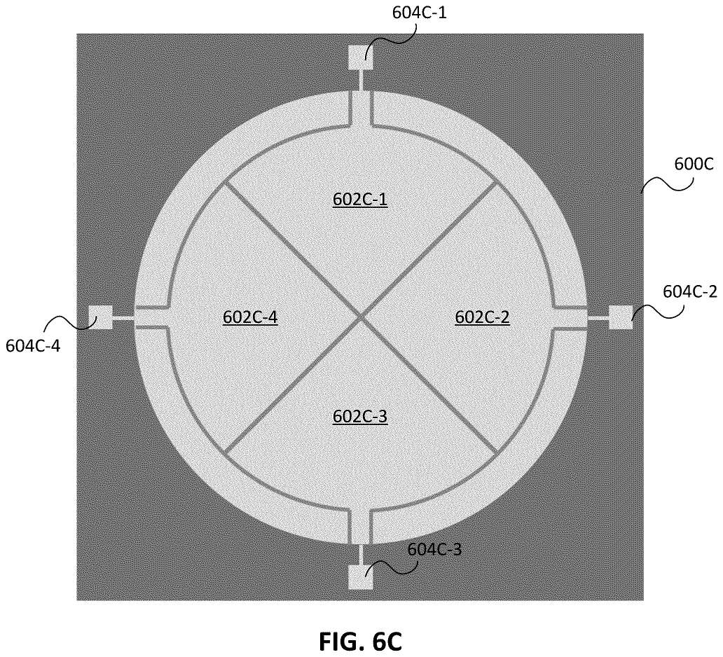

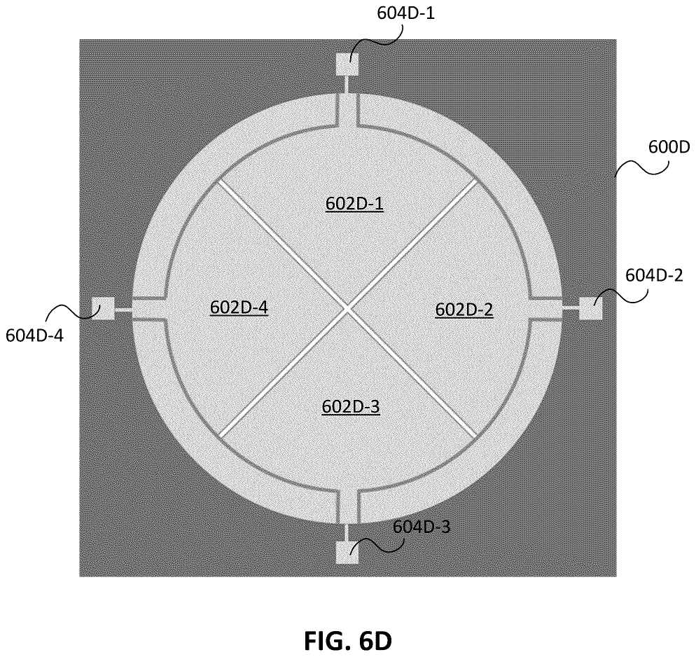

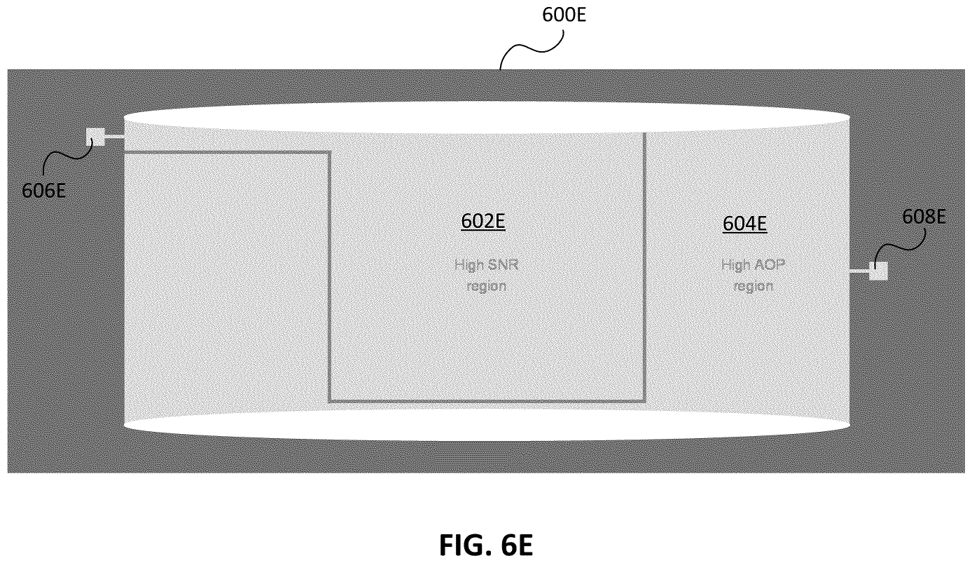

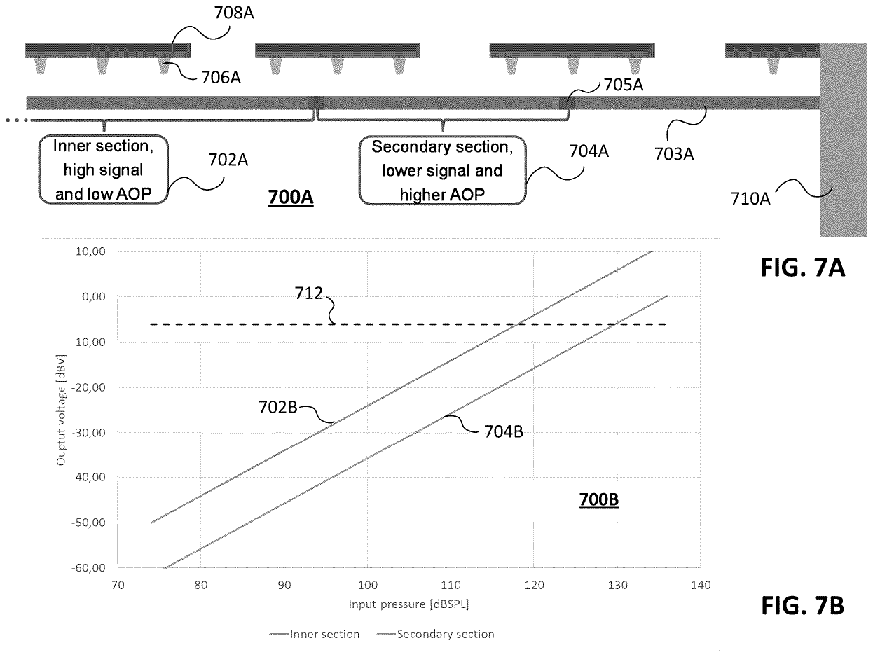

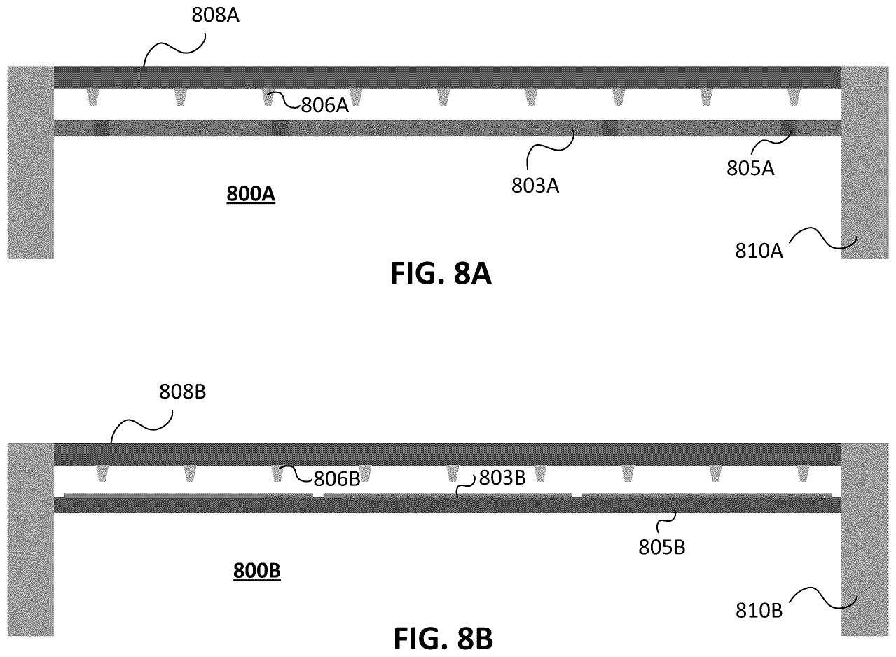

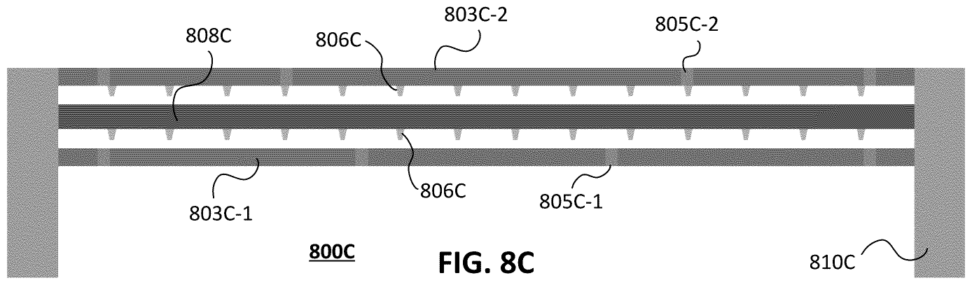

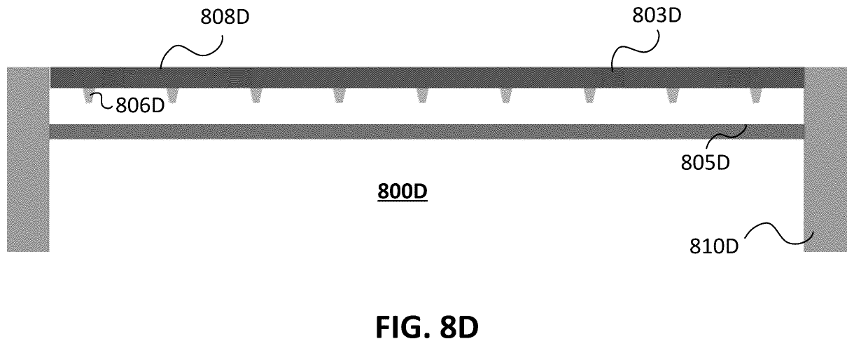

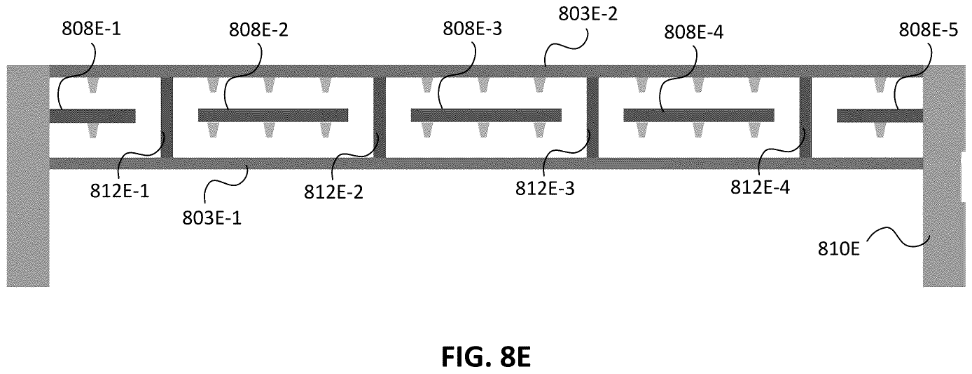

FIGS. 6A, 6B, 6C, 6D and 6E are plan view diagrams of segmented MEMS devices, according to embodiments. In each of these embodiments, the MEMS device or sensor is divided into one or more “high SNR regions” referring to regions having relatively high sensitivity suitable for low or medium input pressures, and one or more “high AOP regions” referring to regions having relatively low sensitivity suitable for high input pressures. The different sections or regions of the single MEMS sensor can be either concentric, radial, or other shapes, each electrically insulated from each other and with their own contact. In some embodiments, the electrical insulation is provided by interstitial regions or layers, and in other embodiments, the electrical insulation is provided by an actual gap between the regions or layers. Further details of these MEMS sensors will be described below with respect to cross-sectional drawings FIGS. 7A, 8A, 8B, 8C, 8D and 8E.

FIG. 6A shows a segmented MEMS sensor 600A comprising a centrally located circular high SNR region 604A surrounded by an annular high AOP region 602A, in an embodiment. High AOP region 602A includes its own contact 606A, and high SNR region 604A includes its own contact 608A. The boundary between the high SNR region 604A and the high AOP region 602A can be fabricated from an insulating material if a conductive membrane is used or from a conductive material if an insulating membrane is used. The embodiment of FIG. 6A can be fabricated as a capacitive MEMS sensor or a piezoelectric MEMS sensor, in embodiments.

FIG. 6B shows a segmented MEMS sensor 600B comprising a centrally located circular high SNR region 604B surrounded by four high AOP regions 602B, in an embodiment. Each high AOP region 602B includes its own contact 606B-1, 606B-2, 606B-3, and 606B-4. In operation, one or more of the high AOP regions 602B can be selected for flexibly combining the outputs of the high SNR region 604B and the one or more high AOP regions 602B. The boundaries between the high SNR region 604B and the high AOP regions 602B, as well as the boundaries between each of the high AOP regions 602B can be fabricated from an insulating material if a conductive membrane is used or from a conductive material if an insulating membrane is used. The embodiment of FIG. 6B can be fabricated as a capacitive MEMS sensor or a piezoelectric MEMS sensor, in embodiments.

FIG. 6C shows a segmented MEMS sensor 600C comprising four wedge-shaped regions 602C-1, 602C-2, 602C-3, and 602C-4, which are isolated from each other. Each wedge-shaped region has its own corresponding contact 604C-1, 604C-2, 604C-3, and 604C-4. In the embodiment of FIG. 6C, the active electrode of the MEMS sensor is split into regions with the same response. The ASIC of the digital microphone can vary the number of sections read in real time based on the input pressure. The active electrodes can be configured at the MEMS sensor to provide two or more outputs with different sensitivities. For example, a high SNR region can be formed activating a first number of the wedge-shaped regions, and a high AOP region can be formed by activating a second number of the wedge-shaped regions, wherein the first number is greater than the second number. Segmented MEMS sensor 600C can be fabricated as a capacitive MEMS sensor, in an embodiment.

FIG. 6D shows a segmented MEMS sensor 600D, with a similar design to that of segmented MEMS sensor 600B of FIG. 6B. Segmented MEMS sensor 600D comprises a plurality of wedge-shaped regions 602D-1, 602D-2, 602D-3, and 602D-4. Each wedge-shaped region has its own corresponding contact 604D-1, 604D-2, 604D-3, and 604D-4. The wedge-shaped regions are insulated from each other by an actual gap between the regions. Thus, segmented MEMS sensor 600D is well suited for fabrication as a piezoelectric version of segmented MEMS sensor 600C.

In some embodiments, the membrane regions of the segmented MEMS sensor need not have a circular symmetry. The example embodiment of segmented MEMS sensor 600E shown in FIG. 6E has a rectangular bridge configuration. Segmented MEMS sensor 600E comprises a first centrally located rectangular high SNR region 602E, and a second peripherally located rectangular high AOP region 604E. High SNR region 602E has its own contact 606E, and high AOP region 604E has its own contact 608D. Segmented MEMS sensor can be fabricated as a capacitive MEMS sensor, in an embodiment.

FIG. 7A is a cross-sectional view of a portion of a segmented MEMS device 700A, according to an embodiment, and FIG. 7B is a graph 700B of the output characteristics of the segmented MEMS device of FIG. 7A.

Segmented MEMS device 700A includes a backplate 708A (also referred to a stator) coupled to a support structure 710A. Backplate 708A is having a plurality of perforation holes. The underside of backplate 708A may include a plurality of anti-stiction bumps 706A. Flexible membrane 703A includes an inner section 702A for generating a relatively higher output signal and a relatively lower AOP with reference to a given input pressure, and a secondary section 704A (or peripheral section) for generating a relatively lower output signal and a relatively higher AOP with reference to the given input pressure. The inner section 702A and secondary section 704A are electrically insulated from each other and from the rest of flexible membrane 703A by a plurality of insulating material regions 705A. Flexible membrane 703A is also coupled to support structure 710A.

Graph 700B shows the output voltages of segmented MEMS device 700A in dBV (y-axis) versus the input pressure impinging on segmented MEMS device 700A in dBSPL (x-axis). While specific output voltages and input pressures are shown in FIG. 7B, these are only example values associated with a particular embodiment, and it will be appreciated by those skilled in the art that other embodiments may result in different specific values. A first output voltage 702B corresponds to the output of inner section 702A, and crosses a maximum input pressure 712 (horizontal line) at about 118 dBSPL. A second output voltage 704B corresponds to the output of secondary section 704A, and crosses the maximum input pressure 712 (horizontal line) at about 130 dBSPL. The “maximum input pressure” represents the input pressure at which programmable gain amplifiers in the ASIC begin to saturate. Thus, as can be seen in FIG. 7B, the first output voltage 702B has a higher gain but lower AOP than the second output voltage 704B, which has a lower gain but higher AOP.

FIGS. 8A, 8B, 8C, 8D and 8E are cross-sectional views of additional segmented MEMS devices, according to embodiments.

FIG. 8A is a cross-sectional diagram of a segmented MEMS device 800A comprising a backplate 808A coupled at both ends to a support structure 810A, wherein the underside of backplate 808A comprises a plurality of anti-stiction bumps 806A. Backplate 808A can comprise a plurality of perforation holes, which are not shown in the cross-sectional diagram of FIG. 8A. Segmented MEMS device 800A also includes a segmented flexible membrane 803A having an inner or central segment that is insulated from peripheral or secondary segments by a plurality of insulating material regions 805A. Thus, segmented MEMS device 800A can be configured for providing two or more outputs, wherein a first output has a higher gain and a lower AOP, and wherein a second output has a lower gain and a high AOP. In the embodiment of segmented MEMS device 800A membrane 803A comprises conductive segments that are insulated with a plurality of insulating material regions 805A.

FIG. 8B is a cross-sectional diagram of a segmented MEMS device 800B comprising a backplate 808B coupled at both ends to a support structure 810B, wherein the underside of backplate 808B comprises a plurality of anti-stiction bumps 806B. Backplate 808B can comprise a plurality of perforation holes, which are not shown in the cross-sectional diagram of FIG. 8B. Segmented MEMS device 800A comprises a plurality of conductive segments 803B on a top surface of a flexible insulating membrane 805B. An inner or central segment is insulated from peripheral or secondary segments by a plurality of air gaps. Thus, segmented MEMS device 800B can also be configured for providing two or more outputs, wherein a first output has a higher gain and a lower AOP, and wherein a second output has a lower gain and a high AOP.

FIG. 8C is a cross-sectional diagram of a closed-cell segmented MEMS device 800C comprising a first flexible membrane 803C-1 having conductive segments that are insulated from each other with insulating material regions 805C-1, and a second flexible membrane 803C-2 having conductive segments that are insulated from each other with insulating material regions 805C-2. Note in FIG. 8C, that the location of the insulating materials regions 805C-1 in the first flexible membrane 803C-1 does not necessarily have to align with the location of the insulating material regions 805C-2 in the second flexible membrane 803C-2. Placement of the insulating material regions in the membrane allows flexibility in the length and placement of the membrane segments, and thus in the gain and AOP of the voltage outputs of MEMS device 800C. The underside of the second flexible membrane 803C-2 comprises a plurality of anti-stiction bumps 806C. Segmented MEMS device 800C also includes a stator 808C located between the first flexible membrane 803C-1 and the second flexible membrane 803C-2. The underside of stator 808C also includes a plurality of anti-stiction bumps 806C. The first flexible membrane 803C-1, the backplane 808C, and the second flexible membrane 803C-2 are all supported by the support structure 810C.

In FIG. 8C, therefore, there is an asymmetry between the membrane segments in the first flexible membrane 803C-1 as compared to the membrane segments in the second flexible membrane 803C-2. The central segment of the first flexible membrane 803C-1 is wider than the central segment of the second flexible membrane 803C-2, such that the central segment of the first flexible membrane 803C-1 can be used for a high gain (high SNR) output. The side segments (peripheral segments) of the second flexible membrane are wider than the peripheral segments of the first flexible membrane 803C-1, which are associated with a high AOP output.

While FIG. 8C illustrates a closed-cell segmented MEMS device 800C having two flexible membranes and a stator interposed between the two flexible membranes, it will be appreciated by those skilled in the art, that the embodiment shown in FIG. 8C can be reconfigured to include two backplates and a flexible membrane interposed between the two backplates in a closed-cell configuration.

FIG. 8D is a cross-sectional diagram of a segmented MEMS device 800D comprising segmented backplate 808D. Backplate 808D includes a plurality of segments that are insulated from each other with a plurality of insulating material regions 803D. As in the other embodiments, the insulating material regions 803D can be configured to define an inner or central segment with a high gain and low AOP, and at least one outer or peripheral segment with a relatively low gain and relatively high AOP. The underside of segmented backplate 808D comprises a plurality of anti-stiction bumps 806D. Segmented MEMS device also includes an unsegmented flexible membrane 805D. The segmented backplate 808D, and the unsegmented flexible membrane 805D are both supported by support structure 810D.

FIG. 8E is a cross-sectional diagram of a closed-cell segmented MEMS device 800E, according to another embodiment. Segmented MEMS device 800E comprising a first flexible membrane 803E-1 and a second flexible membrane 803E-2, each coupled to support structure 810E. The second flexible membrane 803E-2 comprises a plurality of anti-stiction bumps previously described. The first flexible membrane 803E-1 and the second flexible membrane 803E-2 are coupled together with a plurality of pillars, including pillar 812E-1, pillar 812E-2, pillar 812E-3, pillar 812E-4 and pillar 812E-5 forming a plurality of closed cells. Each closed cell comprises a segmented stator segment, including stator segment 808E-1, stator segment 808E-2, stator segment 808E-3, stator segment 808E-4, and stator segment 808E-5. Each stator segment can include anti-stiction bumps previously described. Each stator segment can comprise sub-segments that are insulated from each other. Closed-cell segmented MEMS device 800E is laterally symmetrical about the midpoint point of the MEMS device, in an embodiment.

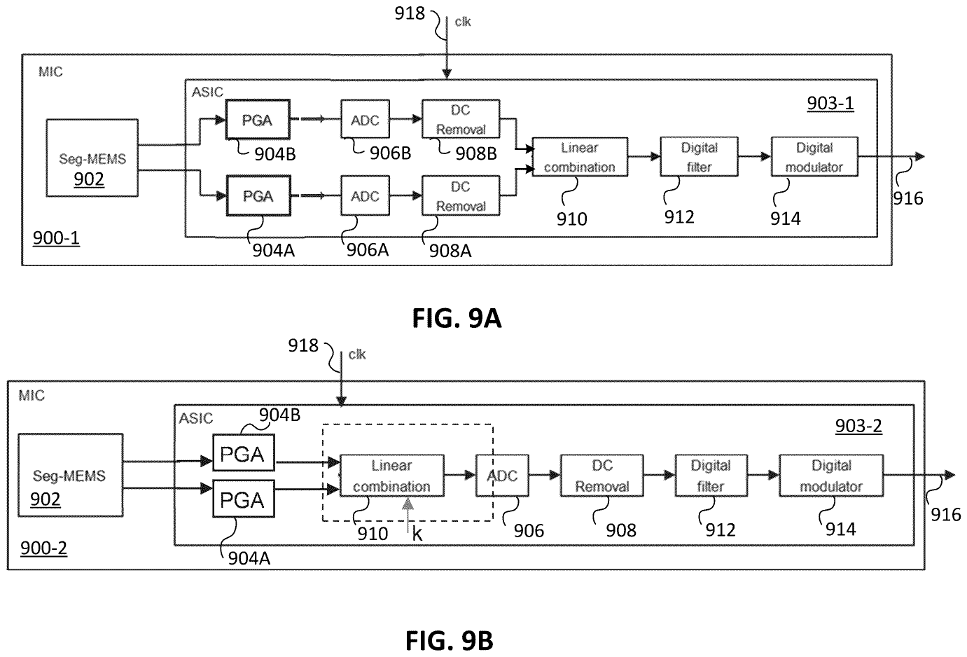

FIGS. 9A and 9B are block diagrams of digital microphones including a segmented MEMS device and a combination circuit, among other signal processing components, according to embodiments.

FIG. 9A is a block diagram of a first digital microphone 900-1 comprising a segmented MEMS device 902 having first and second outputs, corresponding to the high gain low AOP signal output and the low gain high AOP signal output, as previously described. The two outputs of MEMS device 902 are received by an ASIC 903-1. ASIC 903-1 comprising a first programmable gain amplifier (PGA) 904A having an input coupled to the first output of segmented MEMS device 902 and a second PGA 904B having an input coupled to the second output segmented MEMS device 902. A first analog-to-digital converter (ADC) 906A has an input coupled to an output of PGA 904A and a second ADC 906B has an input coupled to an output of PGA 904B. A first DC removal component has an input coupled to an output of ADC 906A and a second DC removal component has an input coupled to an output of ADC 906B. A combination circuit 910, which can comprise a linear combination circuit in some embodiments, has a first input coupled to an output of DC removal component 908A and a second input coupled to an output of DC removal component 908B. A digital filter 912 has an input coupled to an output of the linear combination circuit 910. An optional digital modulator 914 has an input coupled to an output of digital filter 912, and an output for generating a one-bit modulated digital output signal of first digital microphone 900-1 at output node 916. In an embodiment, ASIC 903-1 receives a CLK clock signal at input node 918 for clocking one or more of the signal processing components described above.

When compared to unsegmented MEMS device digital microphone architectures, ASIC 903-1 includes extra signal processing components to process the two output signal from the different response regions of the segmented MEMS device. For example, ASIC 903-1 includes duplicate PGAs 904A and 904B the process a first output signal from a primary section of the segmented MEMS device, and to process a second output signal from a secondary section of the segmented MEMS device. In addition, a combination circuit 910, which can be a linear combination circuit in an embodiment, is included for combining the first and second output signals from the segmented MEMS device. In an embodiment, combination circuit 910 advantageously includes weights that depend on input pressure level so that the two outputs of the segmented MEMS device can be dynamically combined below the maximum AOP level. The dynamically combined output signal of the digital microphone is therefore bounded between the output characteristic of the first output signal of the segmented MEMS device and the second output signal of the segmented MEMS device below the maximum AOP level.

FIG. 9B is a block diagram of a second digital microphone 900-2 comprising a segmented MEMS device 902 having first and second outputs, corresponding to the high gain low AOP signal output and the low gain high AOP signal output, as previously described. The two outputs of MEMS device 902 are received by an ASIC 903-2. ASIC 903-2 comprising a first programmable gain amplifier (PGA) 904A having an input coupled to the first output of segmented MEMS device 902 and a second PGA 904B having an input coupled to the second output segmented MEMS device 902. A combination circuit 910 includes a first input coupled to an output of PGA 904A and a second input coupled to an output of PGA 904B. Combination circuit 910, which can be a linear combination circuit in an embodiment, includes an additional input for receives a dynamic input “k”, which is related to a value of the input pressure. An ADC has an input coupled to an output of combination circuit 910. A DC removal component 908 has an input coupled to an output of ADC 906. A digital filter 912 has an input coupled to an output of DC removal component 908. An optional digital modulator 914 has an input coupled to an output of digital filter 912, and an output for generating a one-bit modulated digital output signal of second digital microphone 900-2 at output node 916. In an embodiment, ASIC 903-1 receives a CLK clock signal at input node 918 for clocking one or more of the signal processing components described above.

In ASIC 903-2 shown in FIG. 9B, the output signals of the segmented MEMS device can thus be combined before the ADC conversion. This approach advantageously reduces both area and power consumption when compared to the embodiment of ASIC 903-1 shown in FIG. 9A. In an embodiment, combination circuit can be merged into the ADC input circuitry sampling circuitry of ADC 906 as suggested by the dashed line block shown in FIG. 9B.

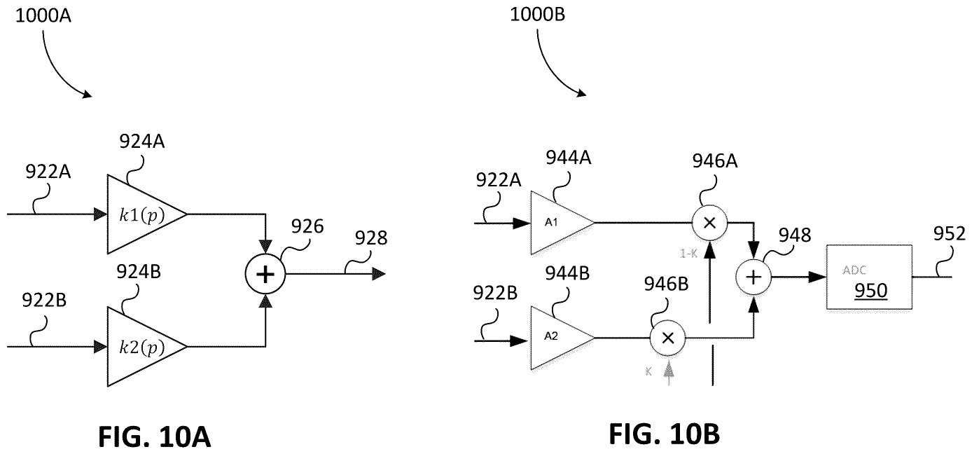

FIGS. 10A and 10B are schematic diagrams of combination circuits, according to embodiments.

FIG. 10A is a schematic diagram of a combination circuit 1000A comprising
a first amplifier 924A having a first weight k1(p), wherein “p” refers to input pressure on the segmented MEMS device, and having a first input 922A; a second amplifier 924B having a second weight k2(p), wherein “p” also refers to input pressure on the segmented MEMS device, and having a second input 922B; and an adder 926 coupled to an output of the first amplifier 924A and to an output of the second amplifier 924B, wherein the first weight k1(p) and the second weight k2(p) are responsive to input sound pressure of an ambient signal.

FIG. 10B is a schematic diagram of an alternative combination circuit 1000B comprising a first amplifier 944A in series connection with a first multiplier 946A; a second amplifier 944B in series connection with a second multiplier 946B; and an adder 948 coupled to an output of the first multiplier 946A and to an output of the second multiplier 946B, wherein a complementary control signal component (1 - K) of the first multiplier 946A and a complementary control signal component (K) of the second multiplier 946B is responsive to input sound pressure of an ambient signal.

The embodiment of combination circuit 1000B may have a smoother transition when combining the two output signal components from the segmented MEMS device. Combination circuit 1000B includes two additional multipliers and a factor K ranging continuously between zero and one depending on the input sound pressure. In an embodiment, adder 948 can be combining with the input circuitry of ADC 950 to save space. The output 952 of ADC 950 can be mapped into the signal processing flow shown in, for example, FIG. 9B, previously described. A calibration of combination circuit 1000B is recommended to ensure optimal functioning.

Combination circuits 1000A and 1000B may linearly combine the two output signals of the segmented devices in embodiments, but other types of combinations can include one or more non-linear functions of input sound pressure to combine the two output signals in other embodiments.

In summary, embodiments of a digital microphone have been descried with two electrical connections to an ASIC. Each connection corresponds to an electrically insulated region of the same structure (membrane or backplate) in a segmented MEMS device or sensor. A subset of the insulated regions is optimized for high SNR output at low acoustic signal. A separate subset of the insulated regions is instead optimized for linearity at high acoustic signal.

The segmented MEMS device of the microphone can be either capacitance-based or piezoelectric. The electrical isolation between the insulated regions in the segmented MEMS device can be achieved by segmenting a conductive layer (e.g. polysilicon) with layers of insulating material (e.g. SiN), or by locally depositing conductive materials (e.g. polysilicon) on an insulating layer (e.g. SiN). The separation between electrodes can be a closed path surrounding the membrane center or patterns moving away from the membrane center is various embodiments.

Embodiments of the segmented MEMS device or sensor are not limited by the number or nature of the electrodes, and can include single backplate, dual backplate, or sealed dual membrane (SDM) embodiments. In the case of more than two membranes, insulating segmentation lines can be offset between different pairs of electrodes. As discussed above both capacitive and piezo-electric segmented MEMS devices can be used in digital microphones, according to embodiments. Finally, an ASIC of the digital microphone can configure the two output signals of the segmented MEMS device in combination, prioritizing SNR or linearity depending on the operating environment.

Example embodiments of the present invention are summarized here. Other embodiments can also be understood from the entirety of the specification and the claims filed herein.

Example 1. According to an embodiment, a system comprises a segmented microelectromechanical system (MEMS) device configured for generating a first signal having a first response to an ambient signal and for generating a second signal having a second response to the ambient signal; and a combination circuit configured for dynamically combining the first signal and the second signal to generate a combined output signal.

Example 2. The system of Example 1, wherein the combination circuit is configured for dynamically combining the first signal and the second signal according to sound pressure of the ambient signal.

Example 3. The system of any of the above examples, wherein the segmented MEMS device comprises at least one segmented membrane or backplate.

Example 4. The system of any of the above examples, wherein the at least one segmented membrane or backplate comprises at least two insulated segments.

Example 5. The system of any of the above examples, wherein the at least one segmented membrane or backplate comprises a high signal-to-noise (SNR) region and a high acoustic overload point (AOP) region.

Example 6. The system of any of the above examples, wherein the combination circuit comprises a first amplifier having a first weight; a second amplifier having a second weight; and an adder coupled to an output of the first amplifier and to an output of the second amplifier, wherein the first weight and the second weight are responsive to sound pressure of the ambient signal.

Example 7. The system of any of the above examples, wherein the combination circuit comprises a first amplifier in series connection with a first multiplier; a second amplifier in series connection with a second multiplier; and an adder coupled to an output of the first multiplier and to an output of the second multiplier, wherein a complementary control signal of the first multiplier and the second multiplier is responsive to sound pressure of the ambient signal.

Example 8. The system of any of the above examples, further comprising a first analog-to-digital converter (ADC) coupled to a first input of the combination circuit; and a second ADC coupled to a second input of the combination circuit.

Example 9. The system of any of the above examples, further comprising an ADC coupled to an output of the combination circuit.

Example 10. The system of any of the above examples, wherein the combination circuit is embodied in an application-specific integrated circuit (ASIC) with at least one ADC.

Example 11. According to an embodiment, a microelectromechanical (MEMS) device comprises a segmented membrane or backplate; and a support structure for supporting the segmented membrane or backplate, wherein the segmented membrane or backplate comprises a high signal-to-noise (SNR) region and a high acoustic overload point (AOP) region.

Example 12. The MEMS device of Example 11, further comprising a sealed dual membrane structure coupled to the support structure, wherein the sealed dual membrane structure includes the segmented membrane.

Example 13. The MEMS device of any of the above examples, further comprising a single backplate coupled to the support structure.

Example 14. The MEMS device of any of the above examples, further comprising a first backplate and a second backplate coupled to the support structure.

Example 15. The MEMS device of any of the above examples, wherein the segmented membrane comprises a piezoelectric segmented membrane.

Example 16. The MEMS device of any of the above examples, wherein the high SNR region comprises a central segment of the segmented membrane or backplate, and wherein the high AOP region comprises one or more peripheral segments of the segmented membrane or backplate.

Example 17. The MEMS device of any of the above examples, wherein the central segment comprises a circular or rectangular segment, and wherein the one or more peripheral segments comprises one or more notched wedge segments or one or more rectangular segments.

Example 18. The MEMS device of any of the above examples, wherein the high SNR region comprises a first number of segments of the segmented membrane or backplate, and wherein the high AOP region comprises a second number of segments of the segmented membrane or backplate, and wherein the first number is different from the second number.

Example 19. The MEMS device of any of the above examples, wherein the segmented membrane comprises a conductive membrane comprising insulating regions for defining a plurality of segments, or an insulating membrane comprising a plurality of conductive segments.

Example 20. According to an embodiment, a method comprises generating a first input signal comprising a high signal-to-noise (SNR) version of a single input signal; generating a second input signal comprising a high acoustic overload point (AOP) version of the single input signal, wherein the first input signal and the second input signal have different responses to the single input signal; dynamically combining the first input signal and the second input signal; and generating a combination output signal bounded by a first input signal response and a second input signal response.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A system comprising:
a segmented microelectromechanical system (MEMS) device configured for generating a first signal having a first response to an ambient signal and for generating a second signal having a second response to the ambient signal; and
a combination circuit configured for dynamically combining the first signal and the second signal to generate a combined output signal.

2. The system of claim 1, wherein the combination circuit is configured for dynamically combining the first signal and the second signal according to sound pressure of the ambient signal.

3. The system of claim 1, wherein the segmented MEMS device comprises at least one segmented membrane or backplate.

4. The system of claim 3, wherein the at least one segmented membrane or backplate comprises at least two insulated segments.

5. The system of claim 3, wherein the at least one segmented membrane or backplate comprises a high signal-to-noise (SNR) region and a high acoustic overload point (AOP) region.

6. The system of claim 1, wherein the combination circuit comprises:
a first amplifier having a first weight;
a second amplifier having a second weight; and
an adder coupled to an output of the first amplifier and to an output of the second amplifier, wherein the first weight and the second weight are responsive to sound pressure of the ambient signal.

7. The system of claim 1, wherein the combination circuit comprises:
a first amplifier in series connection with a first multiplier;
a second amplifier in series connection with a second multiplier; and
an adder coupled to an output of the first multiplier and to an output of the second multiplier, wherein a complementary control signal of the first multiplier and the second multiplier is responsive to sound pressure of the ambient signal.

8. The system of claim 1, further comprising:
a first analog-to-digital converter (ADC) coupled to a first input of the combination circuit; and
a second ADC coupled to a second input of the combination circuit.

9. The system of claim 1, further comprising an ADC coupled to an output of the combination circuit.

10. The system of claim 1, wherein the combination circuit is embodied in an application-specific integrated circuit (ASIC) with at least one ADC.

11. A microelectromechanical (MEMS) device comprising:
a segmented membrane or backplate; and
a support structure for supporting the segmented membrane or backplate, wherein the segmented membrane or backplate comprises a high signal-to-noise (SNR) region and a high acoustic overload point (AOP) region.

12. The MEMS device of claim 11, further comprising a sealed dual membrane structure coupled to the support structure, wherein the sealed dual membrane structure includes the segmented membrane.

13. The MEMS device of claim 11, further comprising a single backplate coupled to the support structure.

14. The MEMS device of claim 11, further comprising a first backplate and a second backplate coupled to the support structure.

15. The MEMS device of claim 11, wherein the segmented membrane comprises a piezoelectric segmented membrane.

16. The MEMS device of claim 11, wherein the high SNR region comprises a central segment of the segmented membrane or backplate, and wherein the high AOP region comprises one or more peripheral segments of the segmented membrane or backplate.

17. The MEMS device of claim 16, wherein the central segment comprises a circular or rectangular segment, and wherein the one or more peripheral segments comprises one or more notched wedge segments or one or more rectangular segments.

18. The MEMS device of claim 11, wherein the high SNR region comprises a first number of segments of the segmented membrane or backplate, and wherein the high AOP region comprises a second number of segments of the segmented membrane or backplate, and wherein the first number is different from the second number.

19. The MEMS device of claim 11, wherein the segmented membrane comprises a conductive membrane comprising insulating regions for defining a plurality of segments, or an insulating membrane comprising a plurality of conductive segments.

20. A method comprising:
generating a first input signal comprising a high signal-to-noise (SNR) version of a single input signal;
generating a second input signal comprising a high acoustic overload point (AOP) version of the single input signal, wherein the first input signal and the second input signal have different responses to the single input signal;
dynamically combining the first input signal and the second input signal; and
generating a combination output signal bounded by a first input signal response and a second input signal response.
